(19) United States
(12) Patent Application Publication
(10) Pub. No.: US 2026/0372075 A1
(43) Pub. Date: Nov. 19, 2026

(54) POWER MODULE UNIT

(71) Applicant: HYUNDAI MOBIS CO., LTD., Seoul (KR)

(72) Inventors: Keun Jae LEE, Yongin-si (KR); Seung Jun NOH, Yongin-si (KR); Min Ki KIM, Yongin-si (KR); So Yeon LEE, Yongin-si (KR)

(73) Assignee: HYUNDAI MOBIS CO., LTD., Seoul (KR)

(21) Appl. No.: 19/428,439

(22) Filed: Dec. 22, 2025

(30) Foreign Application Priority Data
May 13, 2025 (KR) 10-2025-0061979

(51) Int. Cl. H10W 40/22; H10W 40/20; H10W 40/40; H10W 90/00; H10W 90/10

(52) U.S. Cl. CPC H10W 40/22; H10W 40/233; H10W 40/235; H10W 40/40; H10W 90/10; H10W 90/736

(57) ABSTRACT

Disclosed is a power module unit. According to one or more embodiments of the disclosure, a power module unit having a specific shape and an arrangement relationship is provided to improve cooling performance for a power conversion switching device.

### CROSS REFERENCE TO RELATED APPLICATION

The present application claims priority from and the benefit of Korean Patent Application No. 10-2025-0061979, filed on May 13, 2025, the entire content of which is incorporated herein for all purposes by this reference.

### BACKGROUND

### Field

The disclosure relates to a power module unit for stably cooling a power conversion switching device.

### Description of the Related Art

Due to regulations on global environmental pollution and policies for energy efficiency, interest in eco-friendly vehicles or eco-friendly power generation and transmission of solar, wind, and others has recently been growing significantly. In particular, power module units used in the eco-friendly vehicles such as hybrid electric vehicles (HEV), electric vehicles (EV), and fuel cell electric vehicles (FCEVs) are required to have high reliability under more severe conditions because they operate at higher temperature and for longer durations compared to general electronic products.

In addition, as the demand for high-temperature electronics increases in applications such as thermoelectric device packaging and aerospace electronic components, there is a growing need for reliable semiconductor bonding materials and bonding process technologies that can ensure stable operation even under high-temperature conditions.

A representative semiconductor module in high-temperature bonding applications is a power module unit, which is used for power conversion or high-power transmission. The power module unit includes a power semiconductor, a die-attach material, a ceramic substrate or lead-frame, an interconnection material, and a molding and casing material. Recently, research and development have been actively conducted to meet the demands for miniaturization, higher operating voltages, and high-density integration.

For example, a power semiconductor device is installed in a power module unit, and is cooled by a cooler provided in the power module unit.

A conventional cooler for the power module unit will be described with reference to the accompanying drawing.

Referring to FIG. 1, a conventional power module unit includes an insulator 2 serving as a base, an upper heat transfer substrate 3 formed on an upper surface of the insulator 2, and a lower metal substrate 4 formed on a lower surface of the insulator 2.

Further, the conventional power module unit includes a power conversion switching device 5 disposed on an upper surface of the upper the heat transfer substrate 3, and a heat sink (not shown) provided beneath the lower metal substrate 4.

Due to constrains in the size and layout of the power conversion switching device 5, the conventional power module unit has limitations in increasing the thickness of the lower metal substrate 4 or implementing the structure of the heat sink favorable for cooling.

In this case, a path from the power conversion switching device 5 to the heat sink becomes longer, thereby increasing thermal resistance and limiting performance.

Further, the power module unit has an increased total number of components and more complex cooling channels, thereby leading to greater coolant pressure loss and resulting in the need for a higher output pump.

Accordingly, there is a need to reliably cool the power conversion switching device 5 within a limited layout by using the upper and lower the heat transfer substrates 3 and 4 provided in the power module unit.

### SUMMARY

An aspect of the disclosure is to provide a power module unit capable of directly forming a fluid channel, through which a cooling fluid can flow, in a heat transfer substrate, and capable of heat dissipation and heat exchange taking into account locations of a power conversion switching device section.

In one general aspect, a power module unit includes an insulator; a heat transfer section comprising a first heat transfer substrate formed on an upper surface of the insulator, and a second heat transfer substrate formed on a lower surface of the insulator; a power conversion switching device section positioned on an upper surface of the first heat transfer substrate; and a first fluid channel formed in the second heat transfer substrate to provide a plurality of passages for introducing a cooling fluid, wherein the first fluid channel is configured to perform heat exchange with thermal energy generated in the power conversion switching device section, and wherein the first fluid channel comprises an inner maximum diameter that is different in width from an opening.

The first fluid channel may be formed upward from a lower surface of the second heat transfer substrate up to a first height, the inner maximum diameter may be maintained within a region corresponding to the first height, and the opening may remain open on the lower surface of the second heat transfer substrate.

The second heat transfer substrate may have a second height extending from an upper surface thereof to the lower surface, and the second height is within a range of 0.25 to 1.5 mm.

The first height may be within a range of 0.5 to 0.9 times the second height.

The inner maximum diameter may be within a range of 1.0 to 2.0 times the second height.

The opening may be within a range of 0.5 to 1.0 times the inner maximum diameter.

The power conversion switching device section may include a third heat transfer substrate formed with a second fluid channel to transfer the thermal energy in an upward direction.

The second fluid channel may be formed identically to the first fluid channel.

The first fluid channel and the second fluid channel may be formed in any one of a rectangular shape, a polygonal shape, a rhombic shape, a circular shape, and an elliptical shape, or a combination thereof.

In another general aspect, a power module unit includes a power module housing formed with an inlet for introducing a cooling fluid, and an outlet for discharging the cooling fluid introduced through the inlet; an insulator provided inside the power module housing; a heat transfer section comprising a first heat transfer substrate formed on an upper surface of the insulator, and a second heat transfer substrate formed on a lower surface of the insulator; a power conversion switching device section positioned on an upper surface of the first heat transfer substrate and comprising a W-phase power conversion switching device adjacent to the inlet, a V-phase power conversion switching device spaced apart from the W-phase power conversion switching device, and a U-phase power conversion switching device spaced apart from the V-phase power conversion switching device and adjacent to the outlet; and first fluid channels formed in the second heat transfer substrate and having different cross-sectional shapes for heat exchange between the cooling fluid and thermal energy generated in each of the U-phase power conversion switching device, V-phase power conversion switching device, and W-phase power conversion switching device.

The first fluid channels may include a W-phase fluid channel formed below the W-phase power conversion switching device; a V-phase fluid channel formed below the V-phase power conversion switching device; and a U-phase fluid channel formed below the U-phase power conversion switching device.

The first fluid channels may be configured with inner maximum diameters decreasing from the W-phase fluid channel toward the V-phase fluid channel and the U-phase fluid channel.

The W-phase fluid channel may have an inner maximum diameter formed differently from a width of an opening, may be formed upward from a lower surface of the second heat transfer substrate up to a first height, the inner maximum diameter may be maintained within a region corresponding to the first height, and the opening may remain open on the lower surface of the second heat transfer substrate.

The second heat transfer substrate may have a second height extending from an upper surface thereof to the lower surface, and the second height is within a range of 0.25 to 1.5 mm.

The first height may be within a range of 0.5 to 0.9 times the second height.

The inner maximum diameter may be within a range of 1.0 to 2.0 times the second height.

The opening may be within a range of 0.5 to 1.0 times the inner maximum diameter.

The W-phase cooling fluid channel may include a first unit W-phase fluid channel positioned at a predetermined distance from the inlet; and a second unit W-phase fluid channel positioned at a predetermined distance from the first unit W-phase fluid channel, and the first unit W-phase fluid channel is formed to have a larger internal surface area than the second unit W-phase fluid channel.

The power conversion switching device section may include a third heat transfer substrate formed with a second fluid channel to transfer the thermal energy in an upward direction.

The first fluid channels and the second fluid channel may be formed in any one of a rectangular shape, a polygonal shape, a rhombic shape, a circular shape, and an elliptical shape, or a combination thereof.

### BRIEF DESCRIPTION OF THE DRAWINGS

FIG. 1 is a longitudinal cross-sectional view of a conventional power module cooler.

FIG. 2 is a longitudinal cross-sectional view of a power module unit according to a first embodiment of the disclosure.

FIG. 3 is a longitudinal cross-sectional view of a power module unit according to a modified embodiment of the first embodiment of the disclosure.

FIG. 4 is a longitudinal cross-sectional view showing that a first fluid channel and a second fluid channel are formed in the first embodiment of the disclosure.

FIGS. 5 and 6 are longitudinal cross-sectional views of a power module unit according to a second embodiment of the disclosure.

FIGS. 7 and 8 are longitudinal cross-sectional views showing first and second fluid channels according to the second embodiment of the disclosure.

FIGS. 9 and 10 show the heat transfer efficiencies of the first and second fluid channels according to the first and second embodiments of the disclosure.

FIGS. 11 and 12 show heat transfer efficiencies of first and second fluid channels according to another embodiment of the disclosure.

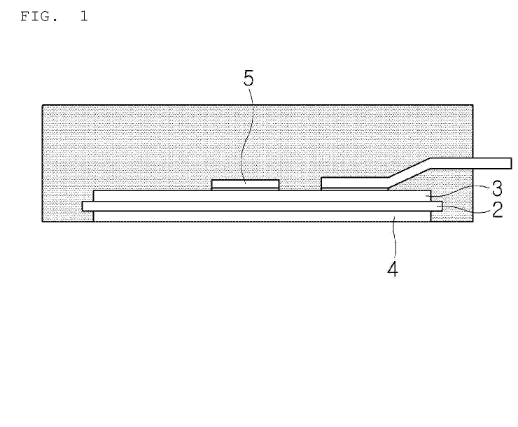

### DETAILED DESCRIPTION

The advantages and features of the disclosure and methods of achieving them will become apparent with reference to the following embodiments described in detail in conjunction with the accompanying drawings. However, the disclosure is not limited to the embodiments set forth herein but may be implemented in various different forms. These embodiments are provided solely to ensure a complete understanding of the disclosure and to fully convey the scope of the disclosure to a person having ordinary knowledge in the art to which the disclosure pertains, and the scope of the disclosure is defined only by the appended claims. Throughout the specification, like reference numerals refer to like elements.

When an element is referred to as being “connected to” or “coupled to” another element, it may be directly connected or coupled to the other element, or connected or coupled to the other element via one or more intervening elements. In contrast, when an element is referred to as being “directly connected to” or “directly coupled to” another element, it means that there are no intervening elements between them. The term “and/or” includes each of the mentioned items as well as any combination of one or more of them.

The terminology used in this specification is for the purpose of describing embodiments only and is not intended to limit the disclosure. In this specification, singular forms include plural forms unless the context clearly indicates otherwise. The terms “comprise” and/or “comprising,” as used in this specification, do not exclude the presence or addition of one or more other elements, steps, operations and/or devices other than the mentioned elements, steps, operations and/or devices.

Although the terms such as “first,” “second,” and the like may be used to describe various elements, it should be understood that these elements are not limited by these terms. These terms are only used to distinguish one element from another element.

The power module unit according to embodiments of the disclosure will be described with reference to the accompanying drawings.

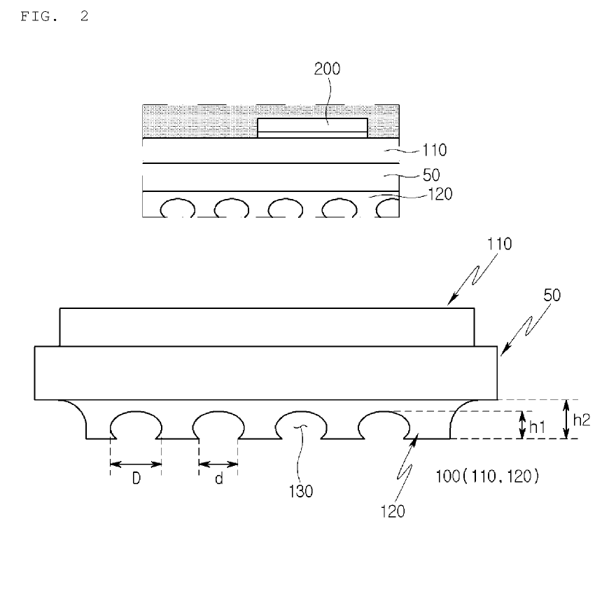

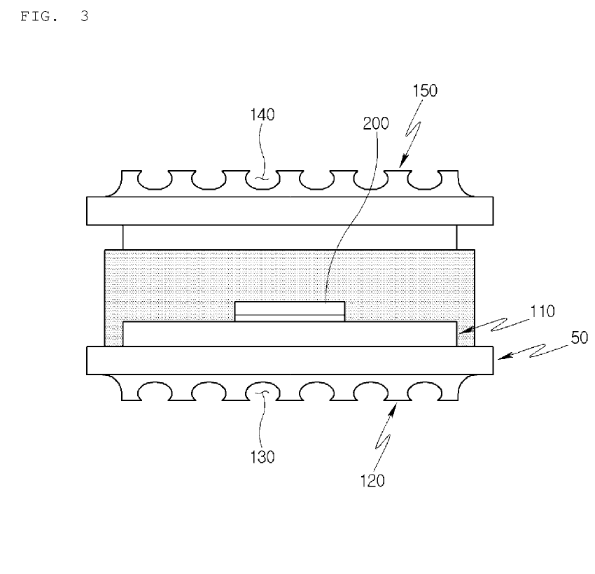

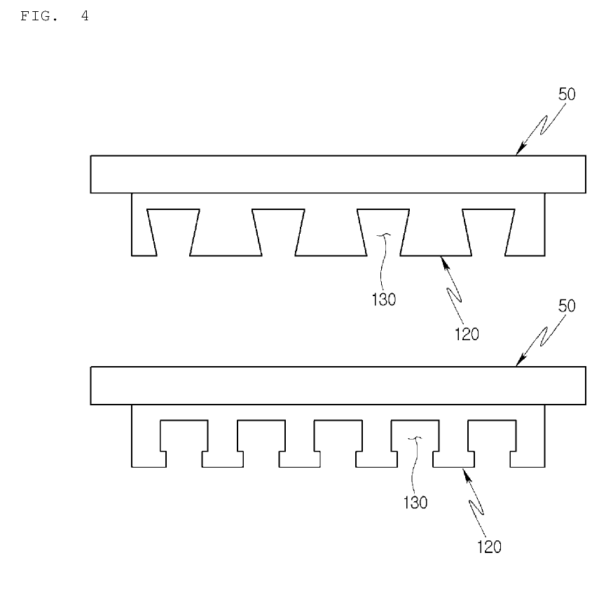

For reference, FIG. 2 is a longitudinal cross-sectional view of a power module unit according to a first embodiment of the disclosure, FIG. 3 is a longitudinal cross-sectional view of a power module unit according to a modified embodiment of the first embodiment of the disclosure, and FIG. 4 is a longitudinal cross-sectional view showing that a first fluid channel and a second fluid channel are formed in the first embodiment of the disclosure.

Referring to FIGS. 2-4, a power module unit according to this embodiment includes an insulator 50; a heat transfer section 100 including a first heat transfer substrate 110 formed on an upper surface of the insulator 50, and a second heat transfer substrate 120 formed on a lower surface of the insulator 50; a power conversion switching device section 200 positioned on an upper surface of the first heat transfer substrate 110; and a first fluid channel 130 which is formed in the second heat transfer substrate 120 to provide a plurality of passages for introducing a cooling fluid, performs heat exchange with thermal energy generated in the power conversion switching device section 200, and includes an inner maximum diameter D different in width from an opening d.

In particular, according to this embodiment, the first fluid channel 130 may be designed with a specific shape and dimensions to enhance a cooling efficiency for the power conversion switching device section 200, thereby implementing optimal cooling performance.

In addition, according to this embodiment, rather than cooling the power conversion switching device section 200 through a conventional heat sink, the first fluid channel 130 through which the cooling fluid can flow may be formed directly in the second heat transfer substrate 120 itself, thereby improving manufacturing convenience and efficiency, reducing the number of parts, and maintaining stable cooling performance, so that the power conversion switching device section 200 can operate reliably even under high-temperature conditions.

In the power module unit according to this embodiment, the first heat transfer substrate 110 is formed on the upper surface of the insulator 50, the second heat transfer substrate 120 is formed on the lower surface of the insulator 50, and the power conversion switching device section 200 is provided on the upper surface of the first heat transfer substrate 110.

The power conversion switching device section 200 includes a plurality of semiconductor devices, and the semiconductor devices generate heat at a high temperature of 200 to over 300 degrees during actual operation.

The first heat transfer substrate 110 and the second heat transfer substrate 120 are configured to receive high-temperature heat generated in the power conversion switching device section 200. In particular, the second heat transfer substrate 120 is formed with the first fluid channel 130 through which the cooling fluid flows.

The second heat transfer substrate 120 has a second height h2 extending from its upper surface to its lower surface, and the second height h2 is selected as a value within a range of 0.25 to 1.5 mm and may be varied without being limited to a specific value.

The first fluid channel 130 is formed upward from the lower surface of the second heat transfer substrate 120 up to a first height h1, and the inner maximum diameter D expanded as much as possible is maintained within a region corresponding to the first height h1.

The first height h1 corresponds to the thickness of the second heat transfer substrate 120, and may for example be selected as a value within a range of 0.5 to 0.9 mm times the second height h2.

The first height h1 corresponds to a passage through which the cooling fluid flows, and the flow of a large amount of cooling fluid may be advantageous for improving the cooling efficiency of the power conversion switching device section 200.

The first height h1 may be variously selected from the aforementioned values in order to achieve both the ease of manufacturing and the improvement in the cooling efficiency when actually manufacturing the second heat transfer substrate 120.

The opening d remains open on the lower surface of the second heat transfer substrate 120, and is formed to be smaller than the inner maximum diameter D. The first fluid channel 130 is configured to have the maximum diameter formed at the center thereof in consideration of temperature distribution based on thermal energy transferred from the power conversion switching device section 200 when the cooling fluid flows. However, the inner maximum diameter D may vary in position from the center to various other positions depending on the shape of the first fluid channel 130.

According to this embodiment, the inner maximum diameter D may be selected as a value within a range of 1.0 to 2.0 mm times the second height h2. When the power conversion switching device section 200 operates at a high temperature, a value of 1.0 mm times the second height h2 may be selected as the inner maximum diameter D to ensure the stable flow of a large amount of cooling fluid.

Because the inner maximum diameter D is greater than the second height h2, flow resistance is reduced when the cooling fluid flows, and an increase in flow resistance at specific locations along the path of the cooling fluid through the first flow channel 130 is prevented.

The opening d may be selected as any value within a range of 0.5 to 1.0 mm times the inner maximum diameter D. The opening d may be formed to have a smaller value than the inner maximum diameter D, but may be varied depending on the flow condition of the cooling fluid.

Referring to FIGS. 3-4, according to this embodiment, cooling may be performed at an upper position of the power conversion switching device section 200 together with the aforementioned first fluid channel 130.

For example, the power conversion switching device section 200 may be provided with a third heat transfer substrate 150 formed with a second fluid channel 140 so that the thermal energy of can be transferred even in an upward direction.

The third heat transfer substrate 150 is made of the same material as the second heat transfer substrate 120 described above, and the second fluid channel 140 is formed identically to the first fluid channel 130.

That is, the second fluid channel 140 may have the same values for the inner maximum diameter D, the first height h1, the second height h2, and the opening d as the first fluid channel 130, or may be formed differently from the first fluid channel 130. For example, the power conversion switching device section 200 transfers more thermal energy toward the second heat transfer substrate 120 than toward the third heat transfer substrate 150.

According to this embodiment, heat exchange with the cooling fluid is performed on the lower and upper sides through the first fluid channel 130 formed on the second heat transfer substrate 120 and the second fluid channel 140 formed on the third heat transfer substrate 150, respectively, thereby maintaining the cooling efficiency stably regardless of the number or position of power conversion switching device section 200.

The first fluid channel 130 is formed on the lower surface of the second heat transfer substrate 120, and may have any one shape selected from elliptical, circular, polygonal, and triangular shapes.

For reference, according to this embodiment, the first fluid channel 130 will be described as being limited to the elliptical shape, but may have various other shapes. For example, the elliptical shape may be replaced by another shape (not shown) as long as its internal surface area is increased.

The first fluid channel 130 and the second fluid channel 140 may be formed in any one of a rectangular shape, a polygonal shape, a rhombic shape, a circular shape, and an elliptical shape, or a combination of these multiple shapes.

In particular, both the first fluid channel 130 and the second fluid channel 140 are formed in a shape in which the internal surface area is maximized, thereby improving the cooling efficiency based on heat transfer.

In this embodiment, the first fluid channel 130 may have a trapezoidal shape in addition to the aforementioned elliptical shape, thereby providing a relatively larger internal surface area than that of the elliptical shape.

In addition, the first fluid channel 130 may have an increased internal surface area when formed in a stepped shape compared to the trapezoidal shape, which can be more advantageous for improving the cooling efficiency.

A power module unit according to another embodiment of the disclosure will be described with reference to the accompanying drawings. In this embodiment, a first fluid channels are formed with various cross-sectional shapes so that heat exchange with a cooling fluid can be simultaneously performed through heat transfer on lower and upper sides, taking into account the flowing direction of the cooling fluid introduced through an inlet of a power module housing, and the positions and heat-generation temperatures of U-, V- and W-phase power conversion switching devices.

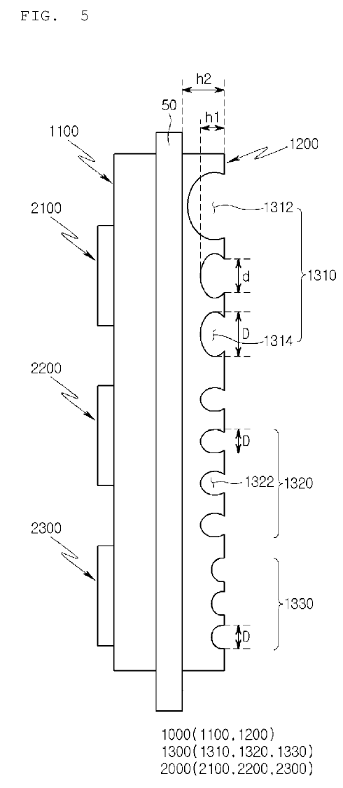

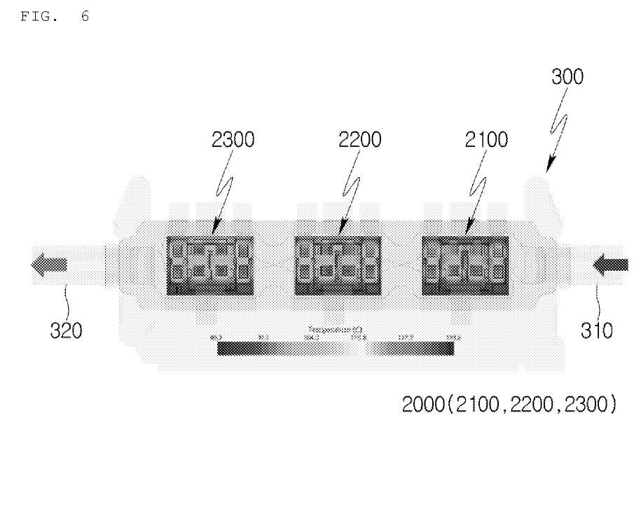

Referring to FIGS. 5-6, a power module unit according to this embodiment includes: a power module housing 300 formed with an inlet 310 for introducing the cooling fluid, and an outlet 320 for discharging the cooling fluid introduced through the inlet 310; an insulator 50 provided inside the power module housing 300; a heat transfer section 1000 including a first heat transfer substrate 1100 formed on an upper surface of the insulator 50, and a second heat transfer substrate 1200 formed on a lower surface of the insulator 50; and a power conversion switching device section 2000 positioned on an upper surface of the first heat transfer substrate 1100 and including a W-phase power conversion switching device 2100 adjacent to the inlet 310, a V-phase power conversion switching device 2200 spaced apart from the W-phase power conversion switching device 2100, and a U-phase power conversion switching device 2300 spaced apart from the V-phase power conversion switching device 2200 and adjacent to the outlet 320.

In addition, the power module unit includes first fluid channels 1300 formed in the second heat transfer substrate 1200 and having different cross-sectional shapes for heat exchange between the cooling fluid and thermal energy generated in each of the U-, V- and W-phase power conversion switching devices 2300, 2200 and 2100.

Referring to FIG. 6, the power module housing 300 has the inlet 310 formed on the right side, and the outlet 320 formed on the left side. The cooling fluid is introduced through the inlet 310, performs the heat exchange while passing through the power conversion switching device section 2000, and is then discharged through the outlet 320.

The power conversion switching device section 2000 includes the W-phase power conversion switching device 2100 disposed in a space between the inlet 310 and the outlet 320.

Further, the V-phase power conversion switching device 2200 is disposed being spaced apart from the left of the W-phase power conversion switching device 2100, and the U-phase power conversion switching device 2300 is disposed being spaced apart from the left of the V-shaped power conversion switching device 2200.

In the power conversion switching device section 2000, the temperature of the W-phase power conversion switching device 2100 adjacent to the inlet 310 is maintained lower than the temperatures of the V-phase power conversion switching device 2200 and the U-phase power conversion switching device 2300 by the cooling fluid.

When the power conversion switching device section 2000 performs the heat exchange with the cooling fluid during actual operation, the heat generation temperature increases from the W-phase power conversion switching device 2100 toward the V-phase power conversion switching device 2200 and the U-phase power conversion switching device 2300.

This embodiment is to optimize heat exchange efficiency by adjusting specific dimensions of the first fluid channels 1300 and second fluid channels 1400 (to be described later) in consideration of the heat generation temperatures according to the positions of the power conversion switching devices.

To this end, the first fluid channels 1300 according to this embodiment include a W-phase fluid channel 1310 formed below the W-phase power conversion switching device 2100, a V-phase fluid channel 1320 formed below the V-phase power conversion switching device 2200, and a U-phase fluid channel 1330 formed below the U-phase power conversion switching device 2300.

The first fluid channels 1300 are configured with the inner maximum diameters D decreasing from the W-phase fluid channel 1310 toward the V-phase fluid channel 1320 and the U-phase fluid channel 1330.

The reason why the first fluid channels 1300 are configured in this way is that, when the cooling fluid, the temperature of which has risen to a predetermined temperature while passing through the W-phase fluid channel 1310, flows to regions where the V-phase fluid channel 1320 and the U-phase fluid channel 1330 are positioned, in sequence, the temperature further rises. Therefore, to enable faster flow and more stable heat exchange of the cooling fluid, the inner maximum diameter D decreases from the W-phase fluid channel 1310 toward the U-phase fluid channel 1330.

As the first fluid channels 1300 are configured in this way, the power conversion switching device section 2000 can be stably cooled by the cooling fluid regardless of its positions even when operating at a high temperature.

The power module unit according to this embodiment includes the first heat transfer substrate 1100 formed on the upper surface of the insulator 50, the second heat transfer substrate 1200 formed on the lower surface of the insulator 50, and the power conversion switching device section provided on the upper surface of the first heat transfer substrate 1100.

The power conversion switching device section includes a plurality of semiconductor devices, and when the semiconductor devices generate heat at a high temperature of 200 to over 300 degrees during actual operation.

The first heat transfer substrate 1100 and the second heat transfer substrate 1200 are configured to receive high-temperature heat generated in the power conversion switching device section. In particular, the second heat transfer substrate 1200 is formed with the first fluid channel 1300 through which the cooling fluid flows.

The first fluid channel 1300 is formed on the lower surface of the second heat transfer substrate 1200, and may have any one shape selected from elliptical, circular, polygonal, and triangular shapes.

In this embodiment, the first fluid channel 1300 will be described as being limited to the elliptical shape, but may have various other shapes.

The opening d remains open on the lower surface of the second heat transfer substrate 1200, and is formed to be smaller than the inner maximum diameter D. The first fluid channel 1300 is configured to have the maximum diameter formed at the center thereof in consideration of temperature distribution based on thermal energy transferred from the power conversion switching device section 2000 when the cooling fluid flows. However, the inner maximum diameter D may vary in position from the center to various other positions depending on the shape of the first fluid channel 1300.

The W-phase fluid channel 1310 has an inner maximum diameter D formed differently from a width of an opening d. The W-phase fluid channel 1310 is formed upward from the lower surface of the second heat transfer substrate 1200 up to a first height h1, and the inner maximum diameter D expanded as much as possible is maintained within a region corresponding to the first height h1. The opening d remains open on the lower surface of the second heat transfer substrate 1200.

The first height h1 corresponds to the thickness of the second heat transfer substrate 1200, and may for example be selected as a value within a range of 0.5 to 0.9 mm times the second height h2.

The first height h1 corresponds to a passage through which the cooling fluid flows, and the flow of a large amount of cooling fluid may be advantageous for improving the cooling efficiency of the power conversion switching device section 2000.

The first height h1 corresponds to the thickness of the second heat transfer substrate 1200, and may for example be selected as a value within a range of 0.5 to 0.9 mm times the second height h2.

The first height h1 may be variously selected from the aforementioned values in order to achieve both the ease of manufacturing and the improvement in the cooling efficiency when actually manufacturing the second heat transfer substrate 1200.

The second heat transfer substrate 1200 has a second height h2 extending from its upper surface to its lower surface, and the second height h2 is selected as a value within a range of 0.25 to 1.5 mm and may be varied without being limited to a specific value.

According to this embodiment, the inner maximum diameter D may be selected as a value within a range of 1.0 to 2.0 mm times the second height h2. When the power conversion switching device section 2000 operates at a high temperature, a value of 1.0 mm times the second height h2 may be selected as the inner maximum diameter D to ensure the stable flow of a large amount of cooling fluid.

Because the inner maximum diameter D is greater than the second height h2, flow resistance is reduced when the cooling fluid flows, and an increase in flow resistance at specific locations along the path of the cooling fluid through the first flow channel 1300 is prevented.

The opening d may be selected as any value within a range of 0.5 to 1.0 mm times the inner maximum diameter D. The opening d may be formed to have a smaller value than the inner maximum diameter D, but may be varied depending on the flow condition of the cooling fluid.

The W-phase cooling fluid 1310 includes a first unit W-phase fluid channel 1312 positioned at a predetermined distance from the inlet 310, and a second unit W-phase fluid channel 1314 positioned at a predetermined distance from the first unit W-phase fluid channel 1312, and the first unit W-phase fluid channel 1312 is formed to have a larger internal surface area than the second unit W-phase fluid channel 1314.

In other words, the overall configuration of the W-phase cooling fluid 1310 includes a predetermined number of first unit W-phase fluid channels 1312 arranged in a horizontal direction, and the second unit W-phase fluid channels 1314 are arranged adjacent to the first unit W-phase fluid channels 1312.

The first unit W-phase fluid channel 1312 has a larger internal surface area than the second unit W-phase fluid channel 1314, thereby maintaining the stable cooling performance for the W-phase power conversion switching device 2100 that operates at high temperatures.

The W-phase fluid channel 1310 may be configured with a ratio of 50:50 between the first unit W-phase fluid channel 1312 and the second unit W-phase fluid channel 1314, or may be configured with a different ratio.

Like the foregoing W-phase fluid channel 1310, the V-phase fluid channel 1320 includes a predetermined number of first unit V-phase fluid channels 1322 arranged in the horizontal direction.

The first unit V-phase fluid channels 1322 may be configured with all identical cross-sectional shapes or with different cross-sectional shapes.

Like the foregoing W-phase fluid channel 1310, the U-phase fluid channel 1330 includes a predetermined number of first unit U-phase fluid channels 1322 arranged in the horizontal direction, and configured with all identical cross-sectional shapes or with different cross-sectional shapes.

When the W-phase fluid channel 1310, the V-phase fluid channel 1320, and the U-phase fluid channel 1330 are configured in this way, their internal surface areas for exchanging heat with the cooling fluid may be adjusted at an optimal ratio according to their positions, thereby improving the cooling performance and consistently ensuring the stable operation of the power conversion switching device section 2000.

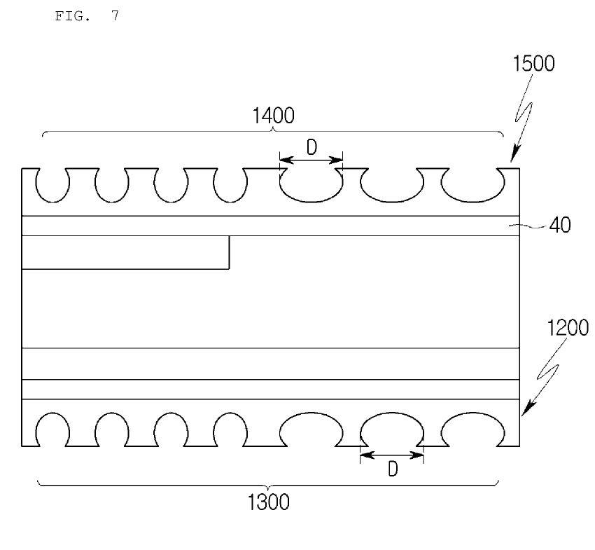

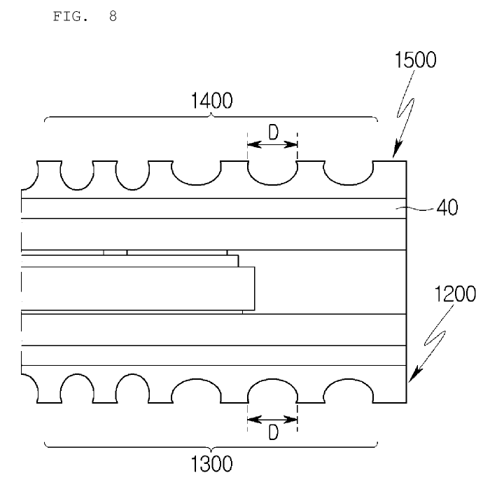

Referring to FIGS. 7 and 8, according to this embodiment, the power conversion switching device section 2000 is provided with a third heat transfer substrate 1500 formed with a second fluid channel 1400 on the upper side so that the thermal energy can be transferred even in an upward direction. For reference, FIGS. 7 and 8 do not explicitly illustrate the power conversion switching device section 2000 based on differences in the cross-sectional direction. In this regard, please refer back to FIGS. 5 and 6.

The third heat transfer substrate 1500 is made of the same material as the second heat transfer substrate 1200 described above, and the second fluid channel 1400 is formed identically to the first fluid channel 1300.

That is, the second fluid channel 1400 may have the same values for the inner maximum diameter D, the first height h1, the second height h2, and the opening d as the first fluid channel 1300, or may be formed differently from the first fluid channel 1300. For example, the power conversion switching device section 2000 transfers more thermal energy toward the second heat transfer substrate 1200 than toward the third heat transfer substrate 1500.

According to this embodiment, heat exchange with the cooling fluid is performed on the lower and upper sides through the first fluid channel 1300 formed on the second heat transfer substrate 120 and the second fluid channel 1400 formed on the third heat transfer substrate 1500, respectively, thereby maintaining the cooling efficiency stably regardless of the number or position of power conversion switching device section 2000.

The first fluid channel 1300 and the second fluid channel 1400 may be formed in any one of a rectangular shape, a polygonal shape, a rhombic shape, a circular shape, and an elliptical shape, or a combination of these multiple shapes.

In particular, both the first fluid channel 1300 and the second fluid channel 1400 are formed in a shape in which the internal surface area is maximized, thereby improving the cooling efficiency based on heat transfer.

In this embodiment, the first fluid channel 1300 may have a trapezoidal shape in addition to the aforementioned elliptical shape, thereby providing a relatively larger internal surface area than that of the elliptical shape.

In addition, the first fluid channel 1300 may have an increased internal surface area when formed in a stepped shape compared to the trapezoidal shape, which can be more advantageous for improving the cooling efficiency.

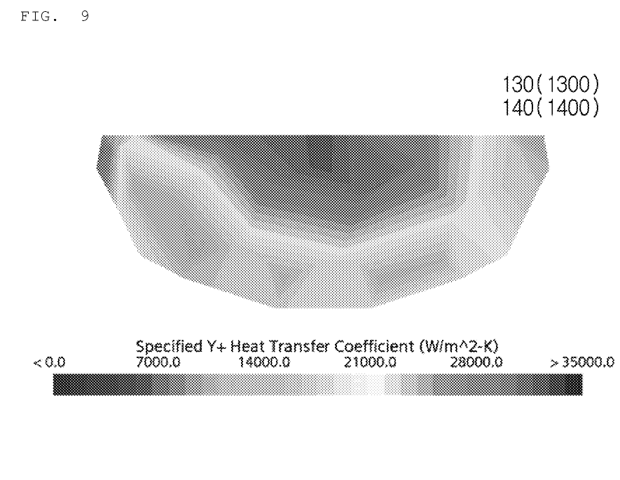

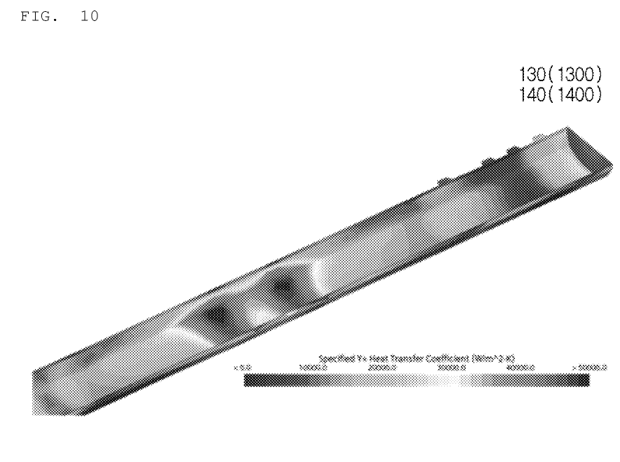

FIGS. 9 and 10 show the heat transfer efficiency of the first and second fluid channels according to the first and second embodiments of the disclosure, in which the first and second fluid channels 130, 140, 1300 and 1400 of the power module unit according to these embodiments are formed to have an elliptical cross-section. In this case, the first and second fluid channels 130, 140, 1300 and 1400 efficiently transfer the high-temperature thermal energy transferred from the power conversion switching device section 200 that operates at a high temperature.

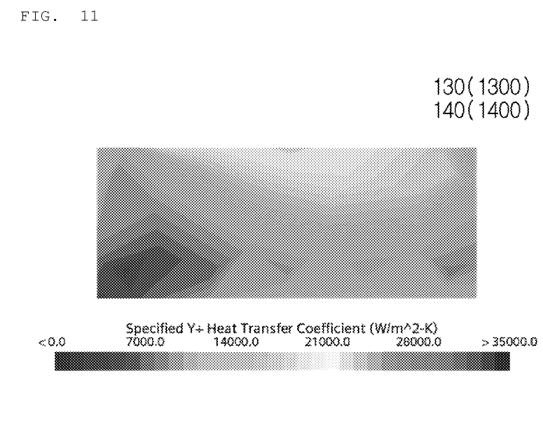

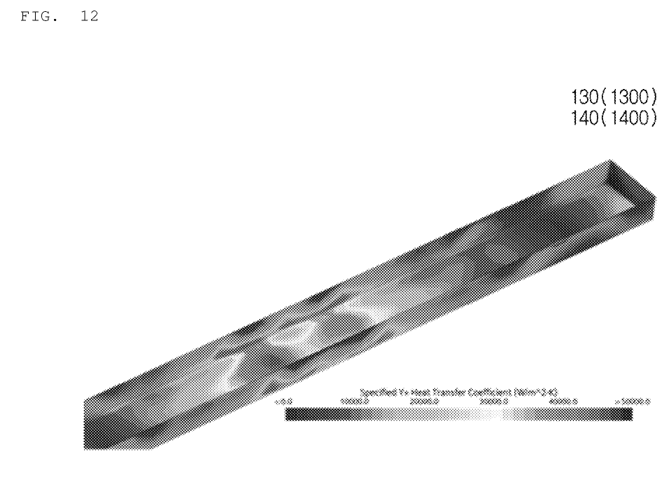

FIGS. 11 and 12 show the heat transfer efficiency of the first and second fluid channels according to another embodiment of the disclosure, in which the first and second fluid channels 130, 140, 1300 and 1400 of the power module unit according to this embodiment efficiently transfer the high-temperature thermal energy transferred from the power conversion switching device section 200 even when they are formed to have a rectangular cross-section rather than the elliptical cross-section.

Therefore, according to these embodiments, the stable cooling for the power conversion switching device section 200 is ensured.

According to the embodiments of the disclosure, a physical length between the power conversion switching device section and the cooling fluid is shortened, and the fluid channel for the flow of the cooling fluid is formed in the heat transfer substrate, thereby maximizing the cooling efficiency.

According to the embodiments of the disclosure, the power conversion switching device section is cooled without the heat sink, thereby reducing the number and weight of parts, and thus achieving overall vehicle weight reduction and improved power efficiency.

According to the embodiments of the disclosure, the fluid channels are respectively provided on the lower and upper sides of the power conversion switching device section, thereby improving the cooling efficiency, and enabling optimal shape and arrangement according to the positions of the U-, V- and W-phase power conversion switching devices.

Although a few embodiments of the disclosure have been described above, modifications and changes can be variously made in the disclosure by a person having ordinary knowledge in the art through addition, alteration, deletion or inclusion of components, etc. without departing from the scope of the disclosure defined in the appended claims, and these are also considered to fall within the scope of the disclosure.

### DESCRIPTION OF REFERENCE NUMERALS

50: insulator
100: heat transfer section
110, 1100: first heat transfer substrate
120, 1200: second heat transfer substrate
130, 1300: first fluid channel
140, 1400: second fluid channel
150: third heat transfer substrate
200, 2000: power conversion switching device section
300: power module housing
310: inlet
320: outlet
2100: W-phase power conversion switching device
2200: V-phase power conversion switching device
2300: U-phase power conversion switching device

What is claimed is:

1. A power module unit comprising:
an insulator;
a heat transfer section comprising a first heat transfer substrate formed on an upper surface of the insulator, and a second heat transfer substrate formed on a lower surface of the insulator;
a power conversion switching device section positioned on an upper surface of the first heat transfer substrate; and
a first fluid channel formed in the second heat transfer substrate to provide a plurality of passages for introducing a cooling fluid,
wherein the first fluid channel is configured to perform heat exchange with thermal energy generated in the power conversion switching device section, and
wherein the first fluid channel comprises an inner maximum diameter that is different in width from an opening.

2. The power module unit of claim 1, wherein
the first fluid channel is formed upward from a lower surface of the second heat transfer substrate up to a first height,
the inner maximum diameter is maintained within a region corresponding to the first height, and
the opening remains open on the lower surface of the second heat transfer substrate.

3. The power module unit of claim 2, wherein the second heat transfer substrate has a second height extending from an upper surface thereof to the lower surface, and the second height is within a range of 0.25 to 1.5 mm.

4. The power module unit of claim 3, wherein the first height is within a range of 0.5 to 0.9 times the second height.

5. The power module unit of claim 3, wherein the inner maximum diameter is within a range of 1.0 to 2.0 times the second height.

6. The power module unit of claim 2, wherein the opening is within a range of 0.5 to 1.0 times the inner maximum diameter.

7. The power module unit of claim 1, wherein the power conversion switching device section comprises a third heat transfer substrate formed with a second fluid channel to transfer the thermal energy in an upward direction.

8. The power module unit of claim 7, wherein the second fluid channel is formed identically to the first fluid channel.

9. The power module unit of claim 7, wherein the first fluid channel and the second fluid channel are formed in any one of a rectangular shape, a polygonal shape, a rhombic shape, a circular shape, and an elliptical shape, or a combination thereof.

10. A power module unit comprising:
a power module housing formed with an inlet for introducing a cooling fluid, and an outlet for discharging the cooling fluid introduced through the inlet;
an insulator provided inside the power module housing;
a heat transfer section comprising a first heat transfer substrate formed on an upper surface of the insulator, and a second heat transfer substrate formed on a lower surface of the insulator;
a power conversion switching device section positioned on an upper surface of the first heat transfer substrate and comprising a W-phase power conversion switching device adjacent to the inlet, a V-phase power conversion switching device spaced apart from the W-phase power conversion switching device, and a U-phase power conversion switching device spaced apart from the V-phase power conversion switching device and adjacent to the outlet; and
first fluid channels formed in the second heat transfer substrate and having different cross-sectional shapes for heat exchange between the cooling fluid and thermal energy generated in each of the U-phase power conversion switching device, V-phase power conversion switching device, and W-phase power conversion switching device.

11. The power module unit of claim 10, wherein the first fluid channels comprise:
a W-phase fluid channel formed below the W-phase power conversion switching device;
a V-phase fluid channel formed below the V-phase power conversion switching device; and
a U-phase fluid channel formed below the U-phase power conversion switching device.

12. The power module unit of claim 11, wherein the first fluid channels are configured with inner maximum diameters decreasing from the W-phase fluid channel toward the V-phase fluid channel and the U-phase fluid channel.

13. The power module unit of claim 11, wherein
the W-phase fluid channel has an inner maximum diameter formed differently from a width of an opening, is formed upward from a lower surface of the second heat transfer substrate up to a first height,
the inner maximum diameter is maintained within a region corresponding to the first height, and
the opening remains open on the lower surface of the second heat transfer substrate.

14. The power module unit of claim 13, wherein
the second heat transfer substrate has a second height extending from an upper surface thereof to the lower surface, and the second height is within a range of 0.25 to 1.5 mm.

15. The power module unit of claim 14, wherein the first height is within a range of 0.5 to 0.9 times the second height.

16. The power module unit of claim 15, wherein the inner maximum diameter is within a range of 1.0 to 2.0 times the second height.

17. The power module unit of claim 13, wherein the opening is within a range of 0.5 to 1.0 times the inner maximum diameter.

18. The power module unit of claim 13, wherein
the W-phase cooling fluid channel comprises:
a first unit W-phase fluid channel positioned at a predetermined distance from the inlet; and
a second unit W-phase fluid channel positioned at a predetermined distance from the first unit W-phase fluid channel, and
the first unit W-phase fluid channel is formed to have a larger internal surface area than the second unit W-phase fluid channel.

19. The power module unit of claim 13, wherein the power conversion switching device section comprises a third heat transfer substrate formed with a second fluid channel to transfer the thermal energy in an upward direction.

20. The power module unit of claim 19, wherein the first fluid channels and the second fluid channel are formed in any one of a rectangular shape, a polygonal shape, a rhombic shape, a circular shape, and an elliptical shape, or a combination thereof.
